(19) United States
(12) Patent Application Publication
(10) Pub. No.: US 2026/0186404 A1
(43) Pub. Date: Jul. 2, 2026

(54) IMPRINT METHOD

(71) Applicant: United Microelectronics Corp., Hsinchu (TW)

(72) Inventors: Yi Lin Tsai, Tainan City (TW); Chih-Hsien Tang, Taipei City (TW)

(73) Assignee: United Microelectronics Corp., Hsinchu (TW)

(21) Appl. No.: 19/048,978

(22) Filed: Feb. 10, 2025

(30) Foreign Application Priority Data
Dec. 30, 2024 (TW) 113151531

(51) Int. Cl. G03F 7/00; B29C 33/38; B29C 43/02; B29C 43/14

(52) U.S. Cl. CPC G03F 7/0002; B29C 33/3842; B29C 43/021; B29C 43/14

(57) ABSTRACT

An imprint method including the following steps is provided. Providing a first master mold including a first protruding pattern and a second protruding pattern. Providing a second master mold including a third protruding pattern. Performing a first imprint step on a first photoresist layer formed on a replica mold by using the first master mold. Performing a first etching step on the replica mold to form a first recessed portion and a second recessed portion. Performing a second imprint step on a second photoresist layer formed on the replica mold by using the second master mold. Performing a second etching step on the replica mold to form a third recessed portion overlapping the first recessed portion. Performing a third imprint step on a third photoresist layer formed on a substrate by using the replica mold. Performing a third etching step on the substrate to form a desired pattern.

### CROSS-REFERENCE TO RELATED APPLICATION

This application claims the priority benefit of Taiwan application serial no. 113151531 filed on Dec. 30, 2024. The entirety of the above-mentioned patent application is hereby incorporated by reference herein and made a part of this specification.

### BACKGROUND

### Technical Field

The disclosure relates to an imprint method, and more particularly to a nanoimprint lithography (NIL) method.

### Description of Related Art

In the existing nanoimprint process, if multiple recessed portions of a replica mold have different widths, after performing the imprint step on the photoresist layer disposed on the substrate by using the replica mold, a relatively large amount of the photoresist layer will remain at a position on the substrate corresponding to the recessed portion having a relatively small width. Therefore, when the substrate is subsequently etched by using the photoresist layer, the etched substrate will have a plurality of patterns with different widths, so as to make a semiconductor device including the substrate have different critical dimensions.

### SUMMARY

The disclosure provides an imprint method, which can enable a plurality of patterns transferred to a substrate to have the substantially equal critical dimensions.

According to an embodiment of the disclosure, the imprint method includes the following steps. Providing a first master mold including a first protruding pattern and a second protruding pattern, wherein a width of the first protruding pattern is less than a width of the second protruding pattern. Providing a second master mold including a third protruding pattern, wherein a width of the third protruding pattern is less than the width of the first protruding pattern. Performing a first imprint step on a first photoresist layer formed on a replica mold by using the first master mold. Performing a first etching step on the replica mold by using the remaining first photoresist layer, so as to form a first recessed portion and a second recessed portion. Performing a second imprint step on a second photoresist layer formed on the replica mold by using the second master mold. Performing a second etching step on the replica mold by using the remaining second photoresist layer, so as to form a third recessed portion, wherein the third recessed portion overlaps the first recessed portion. Performing a third imprint step on a third photoresist layer formed on a substrate by using the replica mold. Performing a third etching step on the substrate by using the remaining third photoresist layer, so as to form a desired pattern.

Based on the above, in the imprint method provided by the embodiment of the disclosure when forming the recessed portion having a relatively small width in the replica mold, two master molds are used to form two recessed portions connected with each other (and overlapped with each other) in a thickness direction of the replica mold, so the connected recessed portions may have a relatively deep depth. Therefore, after performing the subsequent imprint step on the substrate by using the replica mold, the remaining photoresist layer located between the replica mold and the substrate can have a substantially equal thickness, which can reduce the offset of critical dimension generated after performing the subsequent etching process on the substrate, thereby improving the process uniformity and/or increasing the process yield.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIGS. 1A to 1H are schematic diagrams of a flow chart of an imprint method according to an embodiment of the disclosure.

### DESCRIPTION OF THE EMBODIMENTS

The following examples are listed and described in detail with accompanying drawings, but the provided examples are not intended to limit the scope of the disclosure. In addition, the drawings are for illustrative purposes only and are not drawn to original size. To facilitate understanding, the same elements will be identified with the same symbols in the following description.

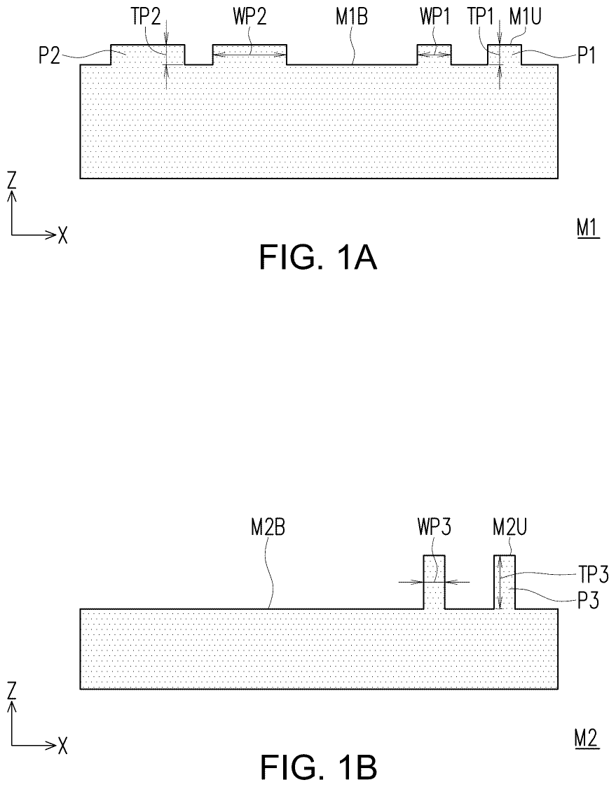

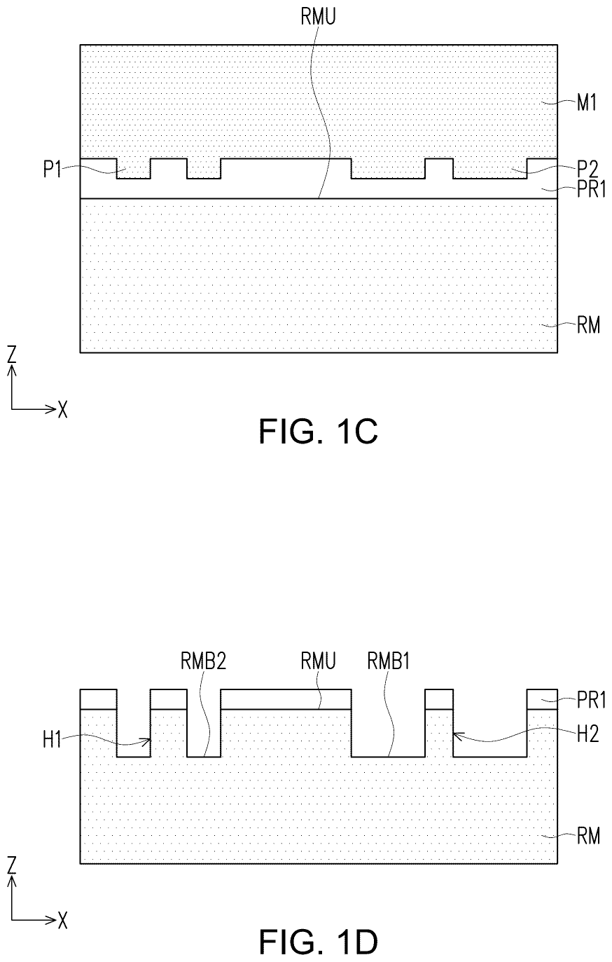

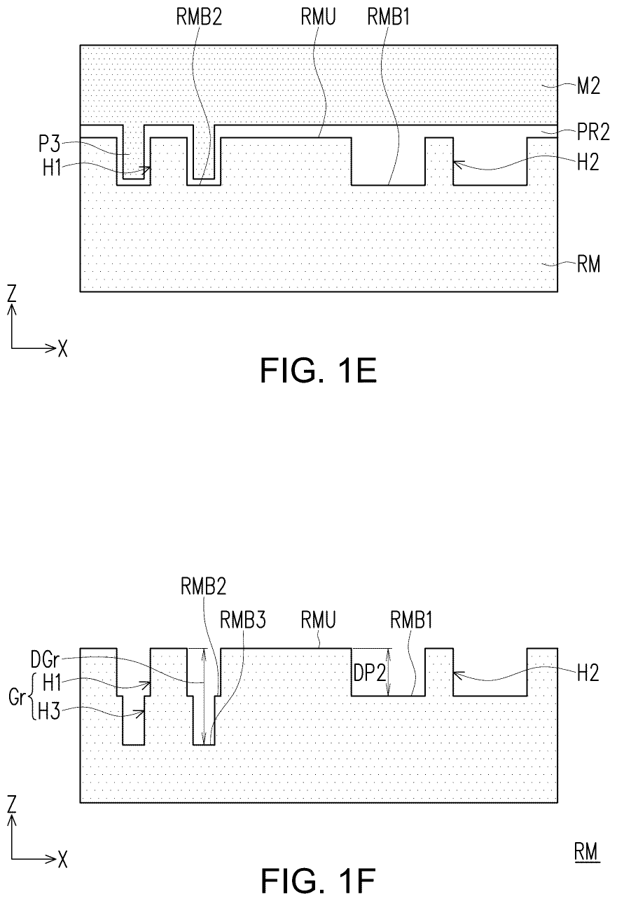

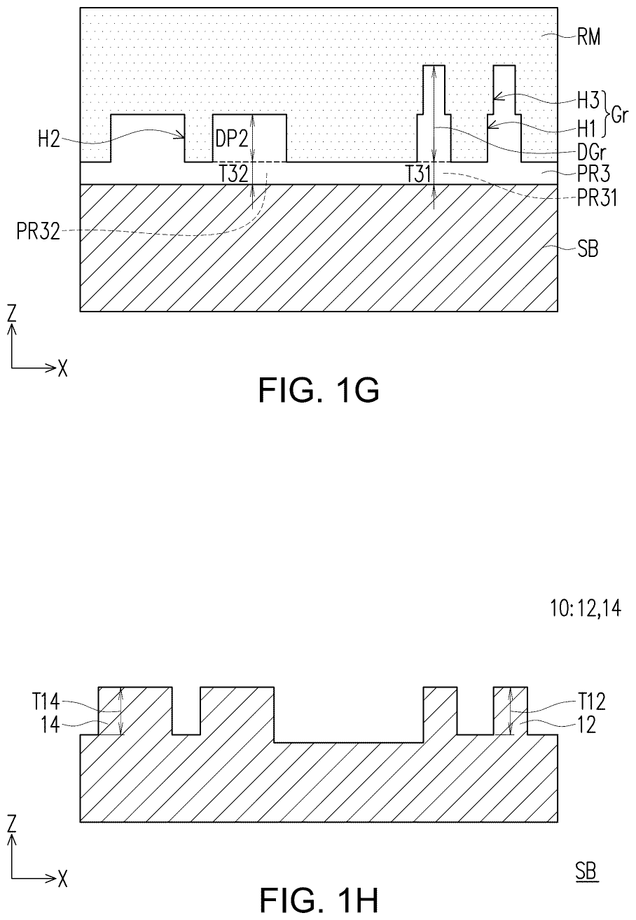

FIGS. 1A to 1H are schematic diagrams of a flow chart of an imprint method according to an embodiment of the disclosure.

Referring to FIG. 1A to FIG. 1H, in the present embodiment, a desired pattern 10 can be formed in a substrate SB by performing an imprint method including the following steps, but the disclosure is not limited thereto.

Step (1a): providing a first master mold M1 including a first protruding pattern P1 and a second protruding pattern P2.

Referring to FIG. 1A, in some embodiments, the first master mold M1 including the first protruding pattern P1 and the second protruding pattern P2 can be formed by performing the following steps, but the disclosure is not limited thereto.

First, forming a first photoresist pattern (not shown) on the first master mold M1. In some embodiments, the first photoresist pattern can be formed on a surface M1U of the first master mold M1 by performing a coating process and an electron beam lithography, but the disclosure is not limited thereto. For example, a first photoresist material layer (not shown) can be formed on the first master mold M1 by performing a spin coating process, a spray coating process, a slit coating process or other suitable coating process. After that, the first photoresist material layer is subjected to the electron beam lithography to form the first photoresist pattern.

In some embodiments, a material of the first photoresist pattern can include an organic material or an inorganic material. For example, the material of the first photoresist pattern includes an organic material, which is photocured material or thermally-cured material, but the disclosure is not limited thereto.

Secondly, performing an etching process on the first master mold M1 by using the first photoresist pattern to form the first protruding pattern P1 and the second protruding pattern P2. In some embodiments, the etching process can include an anisotropic etching process, but the disclosure is not limited thereto. From another perspective, after the etching process is performed on the first master mold M1, a portion of the first master mold M1 is removed to form a bottom surface M1B.

In the present embodiment, a width WP1 of the first protruding pattern P1 is smaller than a width WP2 of the second protruding pattern P2. In detail, the width WP1 of the first protruding pattern P1 in a direction X is smaller than the width WP2 of the second protruding pattern P2 in the direction X. In addition, in the present embodiment, a thickness TP1 of the first protruding pattern P1 is substantially equal to a thickness TP2 of the second protruding pattern P2. In detail, the thickness TP1 of the first protruding pattern P1 in a direction Z is equal to the thickness TP2 of the second protruding pattern P2 in the direction Z, wherein the direction Z is perpendicular to the direction X.

It is worth mentioning that after forming the first master mold M1 including the first protruding pattern P1 and the second protruding pattern P2, the first photoresist pattern is removed to facilitate the subsequent processes.

Step (1b): providing a second master mold M2 including a third protruding pattern P3.

Referring to FIG. 1B, in some embodiments, the second master mold M2 including the third protruding pattern P3 can be formed by performing the following steps, but the disclosure is not limited thereto.

First, forming a second photoresist pattern (not shown) on the second master mold M2. In some embodiments, a method for forming the second photoresist pattern is the same as or similar to the method for forming the first photoresist pattern. In other words, the second photoresist pattern can also be formed on a surface M2U of the second master mold M2 by performing a coating process and an electron beam lithography, but the disclosure is not limited thereto. In addition, a material of the second photoresist pattern can also be the same as or similar to that of the first photoresist pattern, which will be omitted herein.

Secondly, performing an etching process on the second master mold M2 by using the second photoresist pattern to form the third protruding pattern P3. In some embodiments, the etching process can include an anisotropic etching process, but the disclosure is not limited thereto. From another perspective, after the etching process is performed on the second master mold M2, a portion of the second master mold M2 is removed to form a bottom surface M2B.

In the present embodiment, a width WP3 of the third protruding pattern P3 can be smaller than the width WP1 of the first protruding pattern P1. In detail, the width WP3 of the third protruding pattern P3 in the direction X can be smaller than the width WP1 of the first protruding pattern P1 in the direction X, but the disclosure is not limited thereto. In addition, in some embodiments, a thickness TP3 of the third protruding pattern P3 can be greater than the thickness TP1 of the first protruding pattern P1 and the thickness TP2 of the second protruding pattern P2, but the disclosure is not limited thereto.

It is worth mentioning that after forming the second master mold M2 including the third protruding pattern P3, the second photoresist pattern is removed to facilitate the subsequent processes.

Step (2): performing a first imprint step on the first photoresist layer PR1 formed on a replica mold RM by using the first master mold M1.

Referring to FIG. 1C, the first imprint step can include the following steps, but the disclosure is not limited thereto.

First, making the first protruding pattern P1 and the second protruding pattern P2 of the first master mold M1 face the first photoresist layer PR1 formed on a surface RMU of the replica mold RM. In some embodiments, a method for forming the first photoresist layer PR1 can be the same as or similar to the method for forming the first photoresist material layer, and will be omitted herein.

Secondly, performing an imprint process on the first photoresist layer PR1 in the direction Z by using the first master mold M1 to form a plurality of recessed portions in corresponding portions of the first photoresist layer PR1, thereby forming the remaining first photoresist layer PR1. In some embodiments, a portion of the remaining first photoresist layer PR1 is located between the first master mold M1 and the replica mold RM, but the disclosure is not limited thereto. In other embodiments, after performing the imprint process on the first photoresist layer PR1 in the direction Z by using the first master mold M1, the first protruding pattern P1 and the second protruding pattern P2 of the first master mold M1 can contact the replica mold RM.

Afterwards, performing a curing process on the first photoresist layer PR1 that has undergone the imprint process, and removing the first master mold M1.

Step (3): performing a first etching step on the replica mold RM by using the remaining first photoresist layer PR1 to form a first recessed portion H1 and a second recessed portion H2.

Referring to FIG. 1D, in the present embodiment, the remaining first photoresist layer PR1 has a protrusion formed by using the first master mold M1, wherein the protrusion corresponds to the portion other than the first protruding pattern P1 and the second protruding pattern P2 of the first master mold M1. Based on this, the protrusion can be used as a mask to perform an etching process on the replica mold RM to form the first recessed portion H1 and the second recessed portion H2, so as to transfer the first protruding pattern P1 and the second protruding pattern P2 of the first master mold M1 to the replica mold RM. The above etching process can include an anisotropic etching process, but the disclosure is not limited thereto. In some embodiments, a portion of the remaining first photoresist layer PR1 can be removed during the etching process, but the disclosure is not limited thereto. From another perspective, after the etching process is performed on the replica mold RM, a portion of the replica mold RM is removed to form a bottom surface RMB1 and a bottom surface RMB2.

It is worth mentioning that after forming the first recessed portion H1 and the second recessed portion H2, the remaining first photoresist layer PR1 is removed to facilitate the subsequent processes.

Step (4): performing a second imprint step on a second photoresist layer PR2 formed on the replica mold RM by using the second master mold M2.

Referring to FIG. 1E, the second imprint step can include the following steps, but the disclosure is not limited thereto.

First, making the third protruding pattern P3 of the second master mold M2 face the second photoresist layer PR2 formed on the replica mold RM, wherein the second photoresist layer PR2 is filled in the first recessed portion H1 and the second recessed portion H2 of the replica mold RM. In some embodiments, a method for forming the second photoresist layer PR2 can be the same as or similar to the method for forming the first photoresist material layer, and will be omitted herein.

Secondly, performing an imprint process on the second photoresist layer PR2 in the direction Z by using the second master mold M2 to form a plurality of recessed portions in corresponding portions of the second photoresist layer PR2, thereby forming the remaining second photoresist layer PR2. In the present embodiment, the plurality of recessed portions in the remaining second photoresist layer PR2 overlap with the first recessed portion H1 of the replica mold RM. In some embodiments, a portion of the remaining second photoresist layer PR2 is located between the third protruding pattern P3 of the second master mold M2 and the replica mold RM, but the disclosure is not limited thereto. In other embodiments, after performing the imprint process on the second photoresist layer PR2 in the direction Z by using the second master mold M2, the third protruding patterns P3 of the second master mold M2 can contact the replica mold RM.

Afterwards, performing a curing process on the second photoresist layer PR2 that has undergone the imprint process, and removing the second master mold M2.

It is worth mentioning that although the present embodiment shows that the second imprint step is performed after performing the first imprint step, the second imprint step can be performed before performing the first imprint step in other embodiments.

Step (5): performing a second etching step on the replica mold RM by using the remaining second photoresist layer PR2 to form a third recessed portion H3.

Referring to FIG. 1F, in the present embodiment, the remaining second photoresist layer PR2 has a protrusion formed by using the second master mold M2, wherein the protrusion corresponds to the portion other than the third protruding pattern P3 of the second master mold M2. Based on this, the protrusion can be used as a mask to perform an etching process on the replica mold RM to form the third recessed portion H3, so as to transfer the third protruding pattern P3 of the second master mold M2 to the replica mold RM. The above etching process can include an anisotropic etching process, but the disclosure is not limited thereto. In some embodiments, a portion of the remaining second photoresist layer PR2 can be removed during the etching process, but the disclosure is not limited thereto. From another perspective, after the etching process is performed on the replica mold RM, a portion of the replica mold RM is removed to form a bottom surface RMB3.

In the present embodiment, the third recessed portion H3 overlaps with the first recessed portion H1. In detail, the third recessed portion H3 is formed by performing the second etching step on a portion of a bottom surface (the bottom surface RMB3) of the first recessed portion H1 in the direction Z. Therefore, the third recessed portion H3 can be connected to the first recessed portion H1 to form a groove Gr. In the present embodiment, a depth DGr of the groove Gr is greater than a depth DP2 of the second recessed portion H2.

It is worth mentioning that after forming the third recessed portion H3, the remaining second photoresist layer PR2 is removed to facilitate the subsequent processes.

Step (6): performing a third imprint step on a third photoresist layer PR3 formed on a substrate SB by using the replica mold RM.

Referring to FIG. 1G, the third imprint step can include the following steps, but the disclosure is not limited thereto.

First, making the groove Gr and the second recessed portion H2 of the replica mold RM face the third photoresist layer PR3 formed on the substrate SB. In some embodiments, a method for forming the third photoresist layer PR3 can be the same as or similar to the method for forming the first photoresist material layer, and will be omitted herein. In some embodiments, the substrate SB can be a semiconductor substrate. In detail, a material of the substrate SB can include silicon, doped silicon, germanium, silicon germanium, semiconductor compounds, other suitable semiconductor materials, or a combination thereof. For example, the substrate SB can be a silicon substrate, but the disclosure is not limited thereto. In other embodiments, the substrate SB can include a silicon substrate and a conductive layer and/or a dielectric layer formed thereon.

Secondly, performing an imprint process on the third photoresist layer PR3 in the direction Z by using the replica mold RM to form a plurality of recessed portions in corresponding portions of the third photoresist layer PR3, thereby forming the remaining third photoresist layer PR3. In the present embodiment, the remaining third photoresist layer PR3 is filled in the groove Gr and the second recessed portion H2 of the replica mold RM. In some embodiments, a portion of the remaining third photoresist layer PR3 is located between the third protruding pattern P3 of the replica mold RM and the substrate SB. In the present embodiment, since the depth DGr of the groove Gr is greater than the depth DP2 of the second recessed portion H2, the technical problem that a relatively large amount of photoresist layer will remain on a position corresponding the groove Gr having a relatively small width can be solved. Namely, a thickness T31 of the remaining third photoresist layer PR31 not filled in the groove Gr in the direction Z can be substantially the same as a thickness T32 of the remaining third photoresist layer PR32 not filled in the second recess H2. In summary, in the present embodiment, by making the depth DGr of the groove Gr of the replica mold RM greater than the depth DP2 of the second recessed portion H2, which can reduce the offset of critical dimension generated after performing the subsequent etching process on the substrate SB.

Afterwards, performing a curing process on the third photoresist layer PR3 that has undergone the imprint process, and removing the replica mold RM.

Step (7): performing a third etching step on the substrate SB by using the remaining third photoresist layer PR3 to form a desired pattern 10 in the substrate SB.

Referring to FIG. 1H, in the present embodiment, the remaining third photoresist layer PR3 has a protrusion formed by using the replica mold RM, wherein the protrusion corresponds to the groove Gr and the second recessed portion H2 of the replica mold RM. Based on this, the protrusion can be used as a mask to perform an etching process on the substrate SB to form the desired pattern 10, so as to transfer the groove Gr and the second recessed portion H2 of the replica mold RM to the substrate SB. The above etching process can include an anisotropic etching process, but the disclosure is not limited thereto. In some embodiments, a portion of the remaining third photoresist layer PR3 can be removed during the etching process, but the disclosure is not limited thereto.

It is worth mentioning that after forming the desired pattern 10, the remaining third photoresist layer PR3 is removed to facilitate the subsequent processes.

In the present embodiment, the desired pattern 10 includes a first pattern 12 and a second pattern 14. The first pattern 12 can be formed by transferring the first recessed portion H1 of the replication mold RM to the substrate SB, and the second pattern 14 can be formed by transferring the second recessed portions H2 of the replication mold RM to the substrate SB. As described in the above embodiment, by forming the third recessed portion H3 overlapping the first recessed portion H1 in the replica mold RM, the depth DGr of the groove Gr of the replica mold RM can be greater than the depth DP2 of the second recessed portion H2. Therefore, when the width of the first recessed portion H1 is smaller than the width of the second recessed portion H2, the remaining third photoresist layer PR3 located between the third protruding pattern P3 of the replica mold RM and the substrate SB can have the substantially equal thickness after performing the third imprint step. Based on this, the first pattern 12 and the second pattern 14 formed by performing the etching process on the substrate SB can have similar sizes. In detail, in the present embodiment, a thickness T12 of the first pattern 12 in the direction Z can be substantially equal to a thickness T14 of the second pattern 14 in the direction Z.

In summary, in the imprint method provided in the disclosure, a master mold is used to transfer the protruding pattern thereof to a replica mold to form a plurality of recessed portions. When the plurality of recessed portions have different widths, two master molds can be used to sequentially perform the imprint steps on the replica mold. When forming the recessed portion having a relatively small width in the replica mold, two master molds are used to form two recessed portions connected with each other (and overlapped with each other) in a thickness direction of the replica mold, so the connected recessed portions may have a relatively deep depth. Therefore, after performing the subsequent imprint step on the substrate by using the replica mold, the remaining photoresist layer located between the replica mold and the substrate can have a substantially equal thickness, which can reduce the offset of critical dimension generated after performing the subsequent etching process on the substrate, thereby improving the process uniformity and/or increasing the process yield.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. An imprint method, including:
providing a first master mold including a first protruding pattern and a second protruding pattern, wherein a width of the first protruding pattern is less than a width of the second protruding pattern;
providing a second master mold including a third protruding pattern, wherein a width of the third protruding pattern is less than the width of the first protruding pattern;
performing a first imprint step on a first photoresist layer formed on a replica mold by using the first master mold;
performing a first etching step on the replica mold by using the remaining first photoresist layer, so as to form a first recessed portion and a second recessed portion;
performing a second imprint step on a second photoresist layer formed on the replica mold by using the second master mold;
performing a second etching step on the replica mold by using the remaining second photoresist layer, so as to form a third recessed portion, wherein the third recessed portion overlaps the first recessed portion;
performing a third imprint step on a third photoresist layer formed on a substrate by using the replica mold; and
performing a third etching step on the substrate by using the remaining third photoresist layer, so as to form a desired pattern.

2. The imprint method according to claim 1, wherein the third recessed portion is connected to the first recessed portion to form a groove, and a depth of the groove is greater than a depth of the second recessed portion.

3. The imprint method according to claim 1, wherein the first master mold including the first protruding pattern and the second protruding pattern is formed by performing the following steps:
forming a first photoresist pattern on the first master mold; and
performing an etching process on the first master mold by using the first photoresist pattern,
wherein an electron beam lithography is used to form the first photoresist pattern on the first master mold.

4. The imprint method according to claim 1, wherein the second master mold including the third protruding pattern is formed by performing the following steps:
forming a second photoresist pattern on the second master mold; and
performing an etching process on the second master mold by using the second photoresist pattern,
wherein an electron beam lithography is used to form the second photoresist pattern on the second master mold.

5. The imprint method according to claim 1, wherein the second imprint step is performed after performing the first imprint step.

6. The imprint method according to claim 5, wherein the remaining first photoresist layer is removed before performing the second imprint step.

7. The imprint method according to claim 5, wherein the second photoresist layer is filled in the first recessed portion and the second recessed portion.

8. The imprint method according to claim 1, wherein the second imprint step is performed before performing the first imprint step.

9. The imprint method according to claim 1, wherein a curing process is performed on the remaining first photoresist layer before performing the first etching step on the replica mold by using the remaining first photoresist layer.

10. The imprint method according to claim 1, wherein the desired pattern includes a first pattern and a second pattern, the first pattern is transferred from the first recessed portion of the replica mold, the second pattern is transferred from the second recessed portion of the replica mold, and a thickness of the first pattern is substantially equal to a thickness of the second pattern.
